(19) United States
(12) Patent Application Publication
(10) Pub. No.: US 2025/0053526 A1
(43) Pub. Date: Feb. 13, 2025

(54) INFORMATION PROCESSING APPARATUS, INFORMATION PROCESSING METHOD, AND COMPUTER READABLE MEDIUM

(71) Applicant: Mitsubishi Electric Corporation, Tokyo (JP)

(72) Inventors: Yoshitsugu KAWAMURA, Tokyo (JP); Yuki KAWASHIMA, Tokyo (JP)

(73) Assignee: Mitsubishi Electric Corporation, Tokyo (JP)

(21) Appl. No.: 18/931,978

(22) Filed: Oct. 30, 2024

Related U.S. Application Data
(63) Continuation of application No. PCT/JP2022/025032, filed on Jun. 23, 2022.

(51) Int. Cl. G06F 13/22

(52) U.S. Cl. CPC G06F 13/22

(57) ABSTRACT

An extraction unit (101) analyzes device connection information in which a device being a direct connection destination of each device of a plurality of connected devices is described and extracts, among two or more devices whose direct connection destination is common, a pair of devices each of which is not described as a device being a direct connection destination of the other device in the device connection information. An update unit (102) updates the device connection information so that the device connection information describes that each one of the pair of devices extracted by the extraction unit (101) is a device being a direct connection destination of the other device.

### CROSS REFERENCE TO RELATED APPLICATION

This application is a Continuation of PCT International Application No. PCT/JP2022/025032, filed on Jun. 23, 2022, which is hereby expressly incorporated by reference into the present application.

### TECHNICAL FIELD

The present disclosure relates to a technique for analyzing connection relation among devices.

### BACKGROUND ART

As a technique relating to the present disclosure, there is a technique disclosed in Patent Literature 1.

Patent Literature 1 discloses a technique of selecting a candidate for a usable device with use of a system model having connection information among power distribution units and knowledge for selection.

### CITATION LIST

### Patent Literature

Patent Literature 1: JP H10-112937

### SUMMARY OF INVENTION

### Technical Problem

In a designing step for power distribution reception facilities, for instance, it is necessary to determine devices to be used in the power distribution reception facilities. Further, in case where a device installed in power distribution reception facilities is replaced in a maintenance operation step, it is necessary to determine the device to be replaced. Therefore, a method of assisting in determination of the device, that is, a method of recommending the device is necessary.

As such a method of recommending a device, a method with use of collaborative filtering algorithm (which will be simply referred to as collaborative filtering below) is conceivable. In the method of recommending a device with use of the collaborative filtering, the device is recommended with reference to existing connection relation among devices.

In the method of recommending the device with use of the collaborative filtering, there is a problem in that an accuracy of recommendation may be lowered unless connection relation requiring the recommendation of the device coincides with the existing connection relation.

It is one of main objects of the present disclosure to solve such a problem as described above. More specifically, it is a primary object of the present disclosure to increase the accuracy of recommendation in the recommendation of a device with use of the collaborative filtering.

### Solution to Problem

An information processing apparatus according to the present disclosure includes:
an extraction unit to analyze device connection information in which a device being a direct connection destination of each device of a plurality of connected devices is described and to extract, among two or more devices whose direct connection destination is common, a pair of devices each of which is not described as a device being a direct connection destination of the other device in the device connection information; and
an update unit to update the device connection information so that the device connection information describes that each one of the pair of devices extracted by the extraction unit is a device being a direct connection destination of the other device.

### Advantageous Effects of Invention

According to the present disclosure, accuracy of recommendation in the recommendation of a device with use of collaborative filtering can be increased.

### BRIEF DESCRIPTION OF DRAWINGS

FIG. 1 is a diagram illustrating a system configuration example according to Embodiment 1.

FIG. 2 is a diagram illustrating an example of a new-pattern generation screen according to Embodiment 1.

FIG. 3 is a diagram illustrating examples of existing patterns according to Embodiment 1.

FIG. 4 is a diagram illustrating examples of existing patterns according to Embodiment 1.

FIG. 5 is a diagram illustrating an example of pattern information according to Embodiment 1.

FIG. 6 is a diagram illustrating an example of device information according to Embodiment 1.

FIG. 7 is a diagram illustrating an example of device connection information according to Embodiment 1.

FIG. 8 is a diagram illustrating an example of a new pattern according to Embodiment 1.

FIG. 9 is a flowchart illustrating a preliminary process according to Embodiment 1.

FIG. 10 is a flowchart illustrating a recommendation process according to Embodiment 1.

FIG. 11 is a flowchart illustrating a specific example of an extraction process according to Embodiment 1.

FIG. 12 is a flowchart illustrating a specific example of an update process according to Embodiment 1.

FIG. 13 is a diagram illustrating an example of updated device connection information according to Embodiment 1.

FIG. 14 is a diagram illustrating connection relation corresponding to the updated device connection information according to Embodiment 1.

FIG. 15 is a flowchart illustrating a specific example of a recommended device selection process according to Embodiment 1.

FIG. 16 is a diagram illustrating results of counting in the recommended device selection process according to Embodiment 1.

FIG. 17 is a diagram illustrating a hardware configuration example of an information processing apparatus according to Embodiment 1.

### DESCRIPTION OF EMBODIMENTS

Hereinbelow, an embodiment will be described with use of the drawings. In following description on the embodiment and the drawings, elements provided with identical characters represent identical parts or equivalent parts.

### Embodiment 1

In the present embodiment, an example will be described in which a device is recommended based on collaborative filtering when the device is newly installed in power distribution reception facilities or when an existing device set in power distribution reception facilities is replaced by the new device.

### ***Description of Configuration***

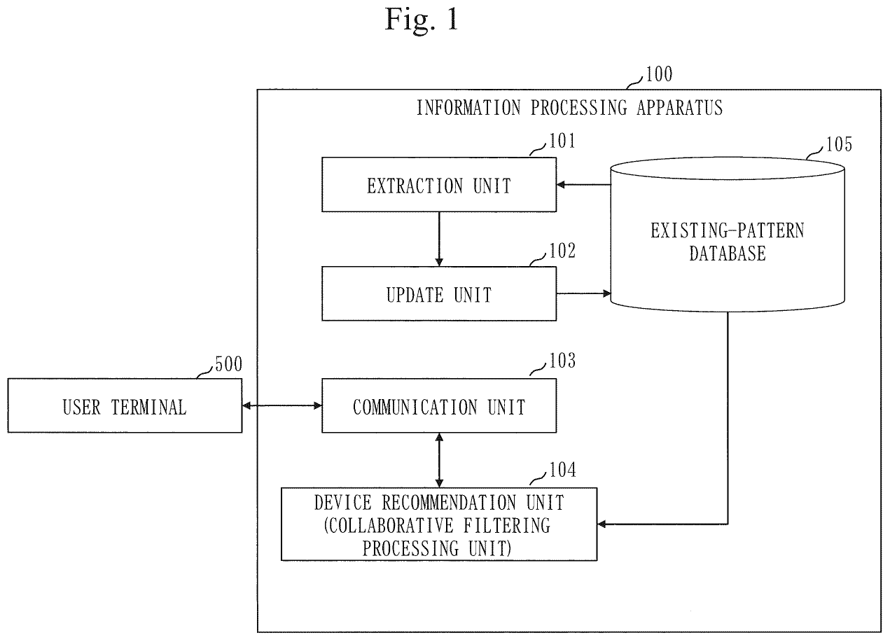

FIG. 1 illustrates a system configuration example according to Embodiment 1.

In FIG. 1, a user terminal 500 is a terminal apparatus to be used by a user. The user terminal 500 is a computer.

The user is a designer to design the power distribution reception facilities, for instance. The user determines a device to be used in the power distribution reception facilities.

An information processing apparatus 100 recommends the user a device to be used in the power distribution reception facilities, based on the collaborative filtering.

The information processing apparatus 100 is also a computer.

A functional configuration and a hardware configuration of the information processing apparatus 100 will be described later.

An operation procedure of the information processing apparatus 100 is equivalent to an information processing method. Further, a program that implements operation of the information processing apparatus 100 is equivalent to an information processing program.

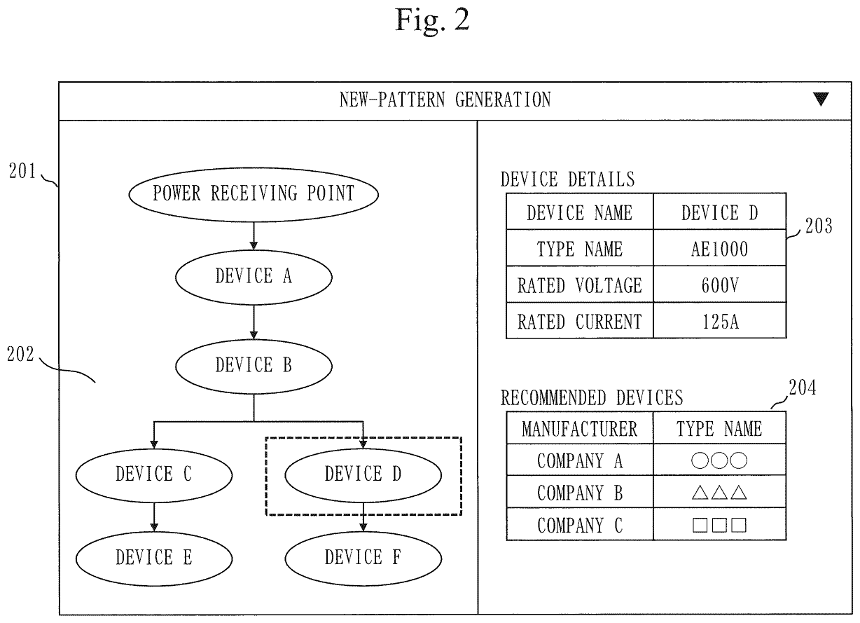

In the present embodiment, the information processing apparatus 100 presents a new-pattern generation screen 201 exemplified in FIG. 2 on the user terminal 500, in accordance with a request from the user terminal 500.

The new-pattern generation screen 201 is a screen that is used in order for the user to generate a new device connection pattern. Connection relation among a plurality of devices is described in a device connection pattern. Hereinbelow, the new device connection pattern will be referred to as new pattern.

The new-pattern generation screen 201 includes an edit area 202, device details 203, and recommended devices 204.

The edit area 202 is used for editing of devices and editing of connections among devices that are for generation of a new pattern. In an initial state, an existing device connection pattern acquired from an existing-pattern database 105 to be described later is displayed in the edit area 202. Hereinbelow, the existing device connection pattern will be referred to as existing pattern. The user is able to carry out addition of a device to the existing pattern, alteration of a device included in the existing pattern, and deletion of a device included in the existing pattern, as the editing of devices, in the edit area 202. Further, the user is able to carry out addition of a connection to the existing pattern, alteration of a connection included in the existing pattern, and deletion of a connection included in the existing pattern, as the editing of connections among devices, in the edit area 202. Further, the user is able to switch display contents of the device details 203 and the recommended devices 204 by designating a device in the edit area 202.

In the device details 203, details of the device designated by the user in the edit area 202 are displayed.

In the recommended devices 204, recommended devices recommended by the information processing apparatus 100 are displayed.

The recommended devices are displayed in the recommended devices 204 in case where the user designates any device displayed in the edit area 202 or in case where the user designates a position which is displayed in the edit area 202 and in which the device is undetermined.

In an example of FIG. 2, a device D has been designated in the edit area 202. Correspondingly, details of the device D are presented in the device details 203. Further, devices that are alternative candidates to the device D are displayed as the recommended devices in the recommended devices 204.

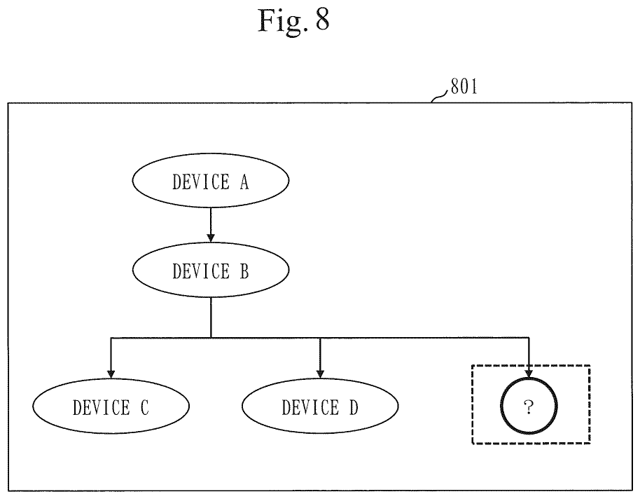

Further, in case where a position in which the device is undetermined (position of “?” in FIG. 8) is designated by the user as illustrated in FIG. 8, devices that are application candidates for the position of “?” are displayed as the recommended devices in the recommended devices 204. Details of FIG. 8 will be described later.

As illustrated in FIG. 2, the information processing apparatus 100 selects devices that are alternative candidates to the device designated by the user, as the recommended devices.

Further, as illustrated in FIG. 8, the information processing apparatus 100 selects the devices that are the application candidates for the position in which the device is undetermined (position of “?” in FIG. 8), as the recommended devices.

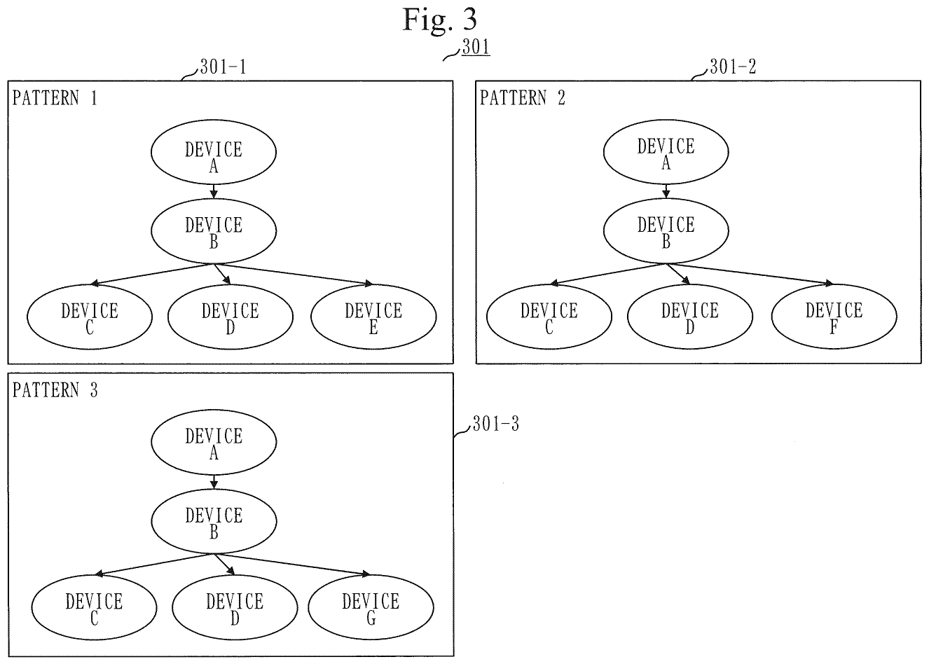

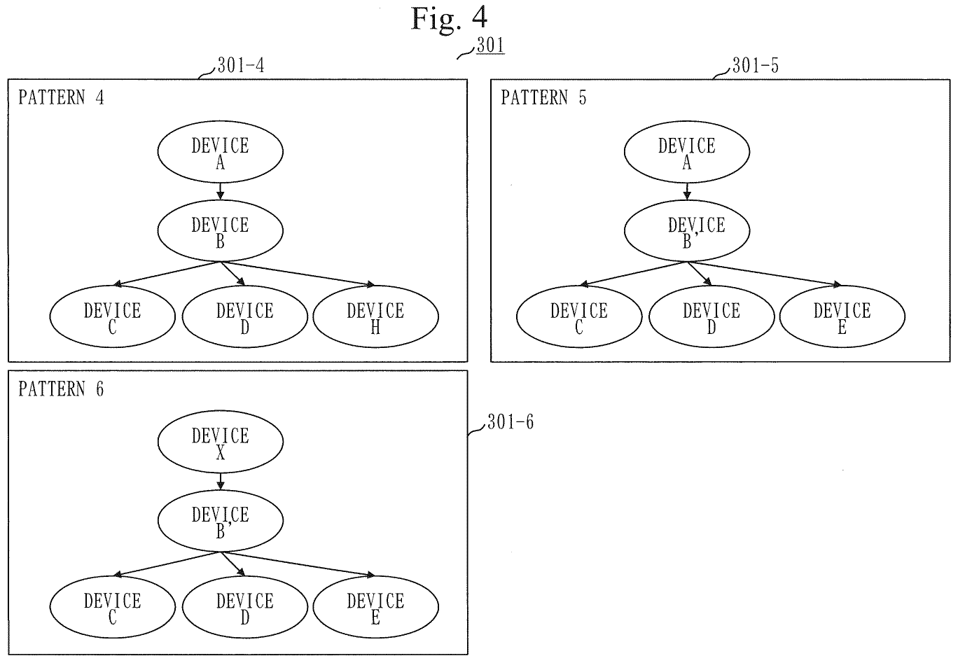

With reference to FIGS. 3 and 4, subsequently, examples of existing patterns that are existing device connection patterns will be described.

In FIG. 3, three existing patterns (pattern 1, pattern 2, and pattern 3) having different combinations of devices are illustrated.

In FIG. 4 as well, three existing patterns (pattern 4, pattern 5, and pattern 6) having different combinations of devices are illustrated.

Incidentally, when it is unnecessary to differentiate between pattern 1 (301-1), the pattern 2 (301-2), the pattern 3 (301-3), the pattern 4 (301-4), the pattern 5 (301-5), and the pattern 6 (301-6), these will be collectively referred to as patterns 301.

Connection relation among a plurality of devices is described in each of the patterns 301.

In the existing-pattern database 105 illustrated in FIG. 1, existing-pattern data that is electronic data having existing patterns presented is retained.

For the editing of devices and/or the editing of connections among devices, the existing-pattern data retained in the existing-pattern database 105 is read out and the existing-pattern data that has been read out is displayed in the edit area 202 on the new-pattern generation screen 201.

Further, in the existing-pattern database 105, pattern information 302 illustrated in FIG. 5 is also retained.

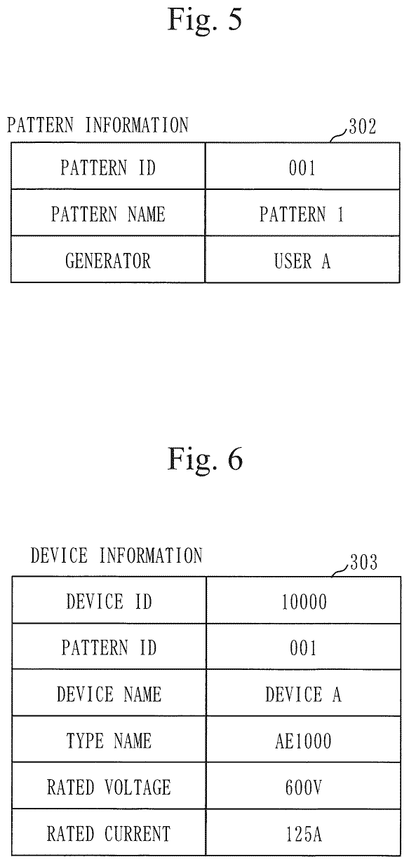

Further, in the existing-pattern database 105, device information 303 illustrated in FIG. 6 is also retained.

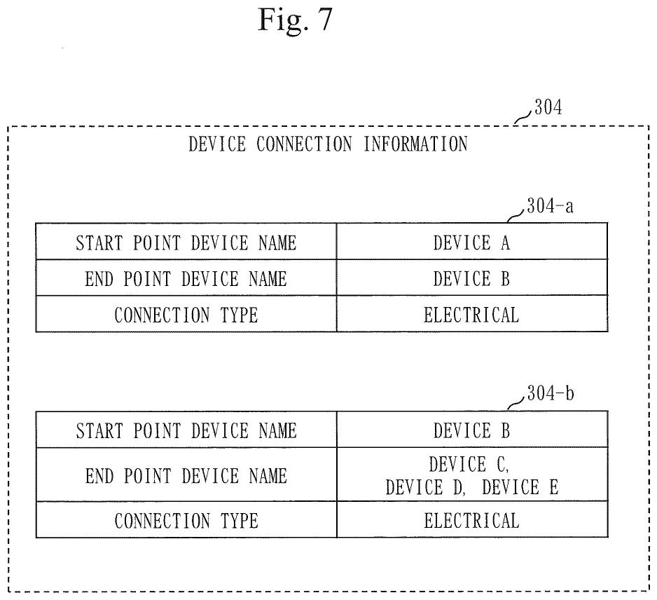

Moreover, in the existing-pattern database 105, device connection information 304-a and device connection information 304-b that are illustrated in FIG. 7 are also retained.

The pattern information 302 specifies details of each of the patterns 301.

In the pattern information 302 of FIG. 5, the details of the pattern 1 (301-1) are specified.

As for the other patterns 301 as well, pattern information similar to the pattern information 302 is provided.

Pattern ID is a unique ID (Identifier) to identify a pattern 301.

Pattern name is a name of the pattern 301.

Generator refers to a generator of the pattern 301.

A device recommendation unit 104 illustrated in FIG. 1 is able to select a device included in any of the patterns 301 as a recommended device, irrespective of the generators of the patterns 301.

That is, the device recommendation unit 104 is able to select a device included in a pattern 301 generated by a generator different from the user generating a new pattern, as a recommended device.

The device information 303 specifies details of each device included in the existing patterns.

In the device information 303 of FIG. 6, details of a device A are specified.

Device ID is a unique ID to identify a device.

Pattern ID is the ID of a pattern 301 in which the device is included. The pattern ID coincides with the pattern ID included in the pattern information 302.

Device name is a name of the device.

Type name is a name of the device as a product. The type name is a model number, a model name, or the like, for instance. A plurality of devices having the same type name may exist in one pattern 301.

Rated voltage and rated current are electrical characteristics of the device.

The device connection information 304-a and the device connection information 304-b each specify connection relation among devices included in a pattern 301.

In the device connection information 304-a and the device connection information 304-b of FIG. 7, the connection relation among devices included in the pattern 1 (301-1) is specified.

Device connection information similar to the device connection information 304-a and the device connection information 304-b is provided for each of the other patterns 301, as well.

Incidentally, when it is unnecessary to differentiate between the device connection information 304-a, the device connection information 304-b, and the device connection information of the other patterns 301, these will be collectively referred to as device connection information 304, below.

In the device connection information 304-a, connection relation between the device A and a device B is specified. In the device connection information 304-b, connection relation between the device B and a device C, a device D, and a device E is specified.

Start point device name is a name of a device (start point device) positioned at a start point of the connection.

End point device name is a name of a device (end point device) positioned at an end point of the connection.

Connection type refers to a connection mode between the start point device and the end point device.

In the device connection information 304-a, “DEVICE A” is written as the start point device name and “DEVICE B” is written as the end point device name. Further, “ELECTRICAL” is written as the connection type. That is, the device connection information 304-a specifies that an electrical connection is made between the device A and the device B.

In the device connection information 304-b, “DEVICE B” is written as the start point device name and “DEVICE C, DEVICE D, DEVICE E” are written as the end point device names. Further, “ELECTRICAL” is written as the connection type. That is, the device connection information 304-b specifies that electrical connections are made between the device B and the device C, the device D, and the device E.

Incidentally, in the electrical connections, the start point device is a device that is close to a power receiving point. On the other hand, the end point device is a device that is close to a load. Incidentally, definitions of the start point device and the end point device may be inverted.

Thus, the devices being direct connection destinations of each device are described in the device connection information 304-a and the device connection information 304-b.

Incidentally, physical, ground, measurement, communication, and the like are conceivable as connection types other than electrical and the devices may be connected by the connection types other than electrical. Further, the devices may be connected by two or more connection types. Embodiment 1, however, is targeted only at the electrical connection relation.

Subsequently, the functional configuration of the information processing apparatus 100 illustrated in FIG. 1 will be described.

An extraction unit 101 analyzes the device connection information 304 and extracts, among two or more devices whose direct connection destination is common, a pair of devices each of which is not described as a device of direct connection destination of the other device in the device connection information 304.

A process that is carried out by the extraction unit 101 is equivalent to an extraction process.

In the device connection information 304-b, for instance, the device B is common as a device of direct connection destination to the device C, the device D, and the device E. The device D that is the other device for the device C, however, is not described as a direct connection destination of the device C in the device connection information 304-b. Further, the device E that is also the other device for the device C is not described as a direct connection destination of the device C in the device connection information 304-b. Moreover, the device C that is the other device for the device D is not described as a direct connection destination of the device D in the device connection information 304-b. Moreover, the device E that is also the other device for the device D is not described as a direct connection destination of the device D in the device connection information 304-b. Similarly, the device C that is the other device for the device E is not described as a direct connection destination of the device E in the device connection information 304-b. Further, the device D that is also the other device for the device E is not described as a direct connection destination of the device E in the device connection information 304-b.

The extraction unit 101 extracts a pair of the device C and the device D, a pair of the device C and the device E, and a pair of the device D and the device E that have such relation.

An update unit 102 updates the device connection information 304 so that the device connection information 304 describes that each one of a pair of devices extracted by the extraction unit 101 is a device of a direct connection destination of the other device.

In an aforementioned example, the update unit 102 updates the device connection information 304 so that the device C and the device D are each specified as a device being a direct connection destination of each other. Further, the update unit 102 updates the device connection information 304 so that the device C and the device E are each specified as a device being a direct connection destination of each other. Moreover, the update unit 102 updates the device connection information 304 so that the device D and the device E are each specified as a device being a direct connection destination of each other.

A process that is carried out by the update unit 102 is equivalent to an update process.

A communication unit 103 communicates with the user terminal 500.

Specifically, the communication unit 103 receives a device recommendation request from the user terminal 500.

Further, the communication unit 103 transmits a response specifying a recommended device selected by the device recommendation unit 104, to the user terminal 500.

The device recommendation unit 104 selects the recommended device, based on the collaborative filtering, in response to the device recommendation request.

The device recommendation unit 104 is equivalent to a collaborative filtering processing unit.

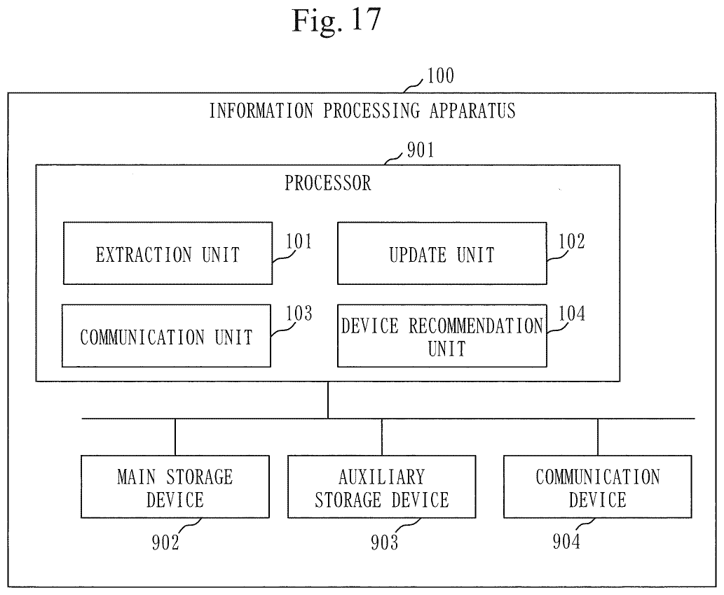

FIG. 17 illustrates a hardware configuration example of the information processing apparatus 100.

The information processing apparatus 100 includes a processor 901, a main storage device 902, an auxiliary storage device 903, and a communication device 904, as hardware.

Programs that implement functions of the extraction unit 101, the update unit 102, the communication unit 103, and the device recommendation unit 104 that are illustrated in FIG. 1 are stored in the auxiliary storage device 903.

The programs are loaded from the auxiliary storage device 903 into the main storage device 902. By executing the programs, the processor 901 carries out operation of the extraction unit 101, the update unit 102, the communication unit 103, and the device recommendation unit 104 that will be described later.

FIG. 17 schematically represents a state in which the processor 901 is executing the programs that implement the functions of the extraction unit 101, the update unit 102, the communication unit 103, and the device recommendation unit 104.

Further, the existing-pattern database 105 illustrated in FIG. 1 is implemented by the auxiliary storage device 903, for instance.

### ***Description of Operation***

It is assumed that a user of the user terminal 500 generates a new pattern 801 illustrated in FIG. 8, for instance.

That is, it is assumed that the new pattern 801 of FIG. 8 is being displayed in the edit area 202 on the new-pattern generation screen 201 of FIG. 2.

In the new pattern 801, there are the device A, the device B, the device C, the device D, and “?”. Further, in the new pattern 801, the device A and the device B are directly connected. Further, the device B and the device C are directly connected. Further, the device B and the device D are directly connected. Further, the device B and “?” are directly connected. Further, the device C and “?” are directly connected. Further, the device D and “?” are directly connected.

A device to be used in a position of “?” in the new pattern 801 is undetermined. The user requests the information processing apparatus 100 to present a recommended device as the device to be applied to the position of “?”.

The user designates “?” and clicks a device recommendation button (not illustrated), for instance, so that a device recommendation request is transmitted from the user terminal 500 to the information processing apparatus 100. Then, recommended devices presented by the information processing apparatus 100 are displayed in the recommended devices 204. The user determines the device to be applied to the position of “?” by reference to the recommended devices displayed in the recommended devices 204.

Herein, when only the existing-pattern data corresponding to the patterns 301 illustrated in FIGS. 3 and 4 is retained in the existing-pattern database 105, there is a fear that the device recommendation unit 104 may be unable to select an appropriate recommended device.

In the pattern 1 (301-1), direct connections are made between the device B and the device C, between the device B and the device D, and between the device B and the device E. No direct connections, however, are made between the device C and the device D, between the device C and the device E, and between the device D and the device E.

The other patterns 301 also have similar connection relation. That is, no direct connections are made between devices below the device B (or a device B′) in the other patterns 301 as well.

In the new pattern 801 of FIG. 8, by contrast, direct connections are made between the device C and the device D, between the device C and the device “?”, and between the device D and “?”, as described above. That is, the direct connections are made between devices below the device B.

There is a fear that it may be impossible to recommend an appropriate device if device recommendation based on the collaborative filtering is made with use of a pattern 301 in which connection relation differing from the connection relation of the new pattern 801 is described.

For coping with this, in the present embodiment, the device connection information 304 is updated by the extraction unit 101 and the update unit 102.

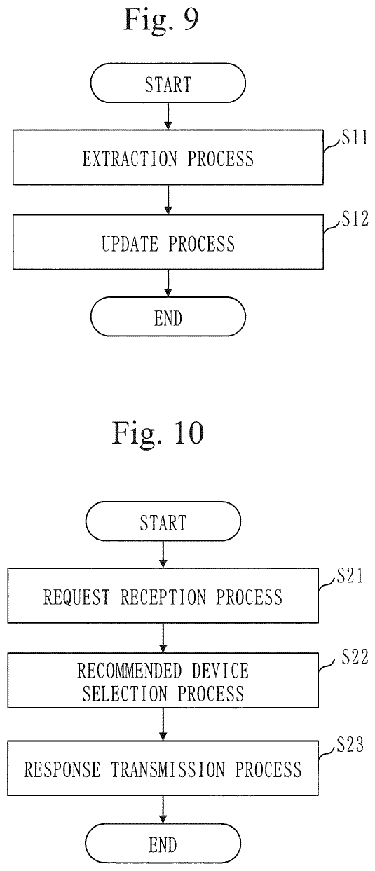

FIG. 9 illustrates a preliminary process by the extraction unit 101 and the update unit 102.

Further, FIG. 10 illustrates a recommendation process by the communication unit 103 and the device recommendation unit 104.

Execution of FIG. 10 is preceded by execution of FIG. 9.

In step S11 of FIG. 9, initially, the extraction unit 101 carries out the extraction process.

That is, the extraction unit 101 analyzes the device connection information 304 and extracts, among two or more devices having a common device of direct connection destination, a pair of devices each of which is not described as a device being a direct connection destination of the other device in the device connection information 304.

In step S12, subsequently, the update unit 102 carries out the update process.

That is, the update unit 102 updates the device connection information 304 so that the device connection information 304 describes that each one of the pair of devices extracted by the extraction unit 101 is a device being a direct connection destination of the other device.

In step S21 in FIG. 10, the communication unit 103 carries out a request reception process.

That is, the communication unit 103 receives a device recommendation request from the user terminal 500.

In step S22, subsequently, the device recommendation unit 104 carries out a recommended device selection process.

That is, the device recommendation unit 104 selects recommended devices, based on the collaborative filtering with use of the device connection information 304 updated in step S12.

In step S23, subsequently, the communication unit 103 carries out a response transmission process.

That is, the communication unit 103 transmits a response specifying the recommended devices selected by the device recommendation unit 104, to the user terminal 500.

As a result, the recommended devices are displayed in the recommended devices 204 on the new-pattern generation screen 201.

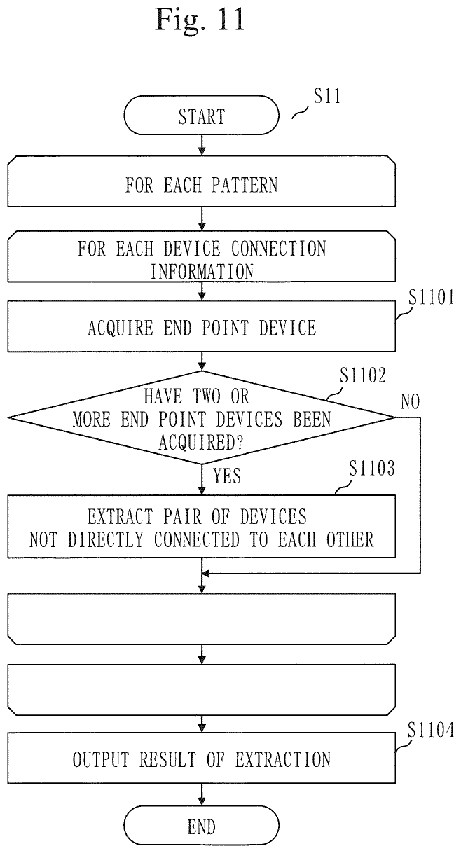

With reference to FIG. 11, subsequently, details of the extraction process (step S11) illustrated in FIG. 9 will be described.

The extraction unit 101 carries out steps S1101 to S1103 for each device connection information 304 of each of the patterns 301.

In step S1101, the extraction unit 101 acquires end point devices described in the device connection information 304.

In step S1102, subsequently, the extraction unit 101 determines whether two or more end point devices have been acquired or not.

If the extraction unit 101 has not acquired two or more end point devices (NO in step S1102), the process returns to step S1101 and the extraction unit 101 acquires end point devices from the subsequent device connection information 304.

If the extraction unit 101 has acquired two or more end point devices (YES in step S1102), by contrast, the process proceeds to step S1103.

In step S1103, the extraction unit 101 extracts a pair of devices that are not directly connected to each other.

After steps S1101 to S1103 are carried out for the overall device connection information 304 of all the patterns, the extraction unit 101 outputs a result of extraction to the update unit 102 in step S1104.

Herein, details of steps S1101 to S1103 will be described with use of an example of the device connection information 304-b.

In the device connection information 304-b, the device C, the device D, and the device E are listed as the end point devices. In step S1101, accordingly, the extraction unit 101 acquires the device C, the device D, and the device E as the end point devices from the device connection information 304-b.

A determination of YES is made in step S1102, because the three devices have been extracted in step S1101, and the process proceeds to step S1103.

In step S1103, the extraction unit 101 extracts the pair of the device C and the device D, the pair of the device C and the device E, and the pair of the device D and the device E as pairs of devices that are not directly connected to each other.

Specifically, the extraction unit 101 determines whether the device connection information 304 in which the device C is written as the start point device exists or not in the pattern 1 (301-1).

If the device connection information 304 in which the device C is written as the start point device exists in the pattern 1 (301-1), the extraction unit 101 determines whether the device D is written as the end point device or not in the device connection information 304.

If the device D is written as the end point device, the extraction unit 101 determines that the device C is directly connected to the device D.

If the device connection information 304 in which the device C is written as the start point device does not exist, the extraction unit 101 determines that the device C is neither connected directly to the device D nor the device E.

If the device connection information 304 in which the device C is written as the start point device exists and if the device D is not written as the end point device in the device connection information 304, the extraction unit 101 determines that the device C is not directly connected to the device D.

The extraction unit 101 determines presence or absence of the direct connection between the device C and the device E in a similar scheme.

Further, the extraction unit 101 determines presence or absence of the direct connection between the device D and the device E in a similar scheme.

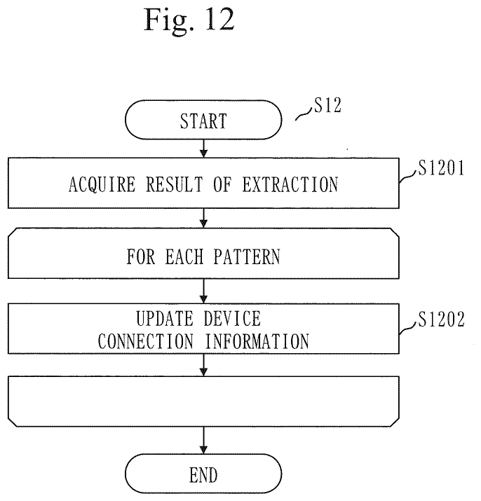

With reference to FIG. 12, subsequently, details of the update process (step S12) illustrated in FIG. 9 will be described.

In step S1201, initially, the update unit 102 acquires the result of extraction outputted in step S1104 of FIG. 11.

In step S1202, subsequently, the update unit 102 updates the device connection information 304, based on the result of extraction by the extraction unit 101.

The update unit 102 carries out step S1202 for each of the patterns 301.

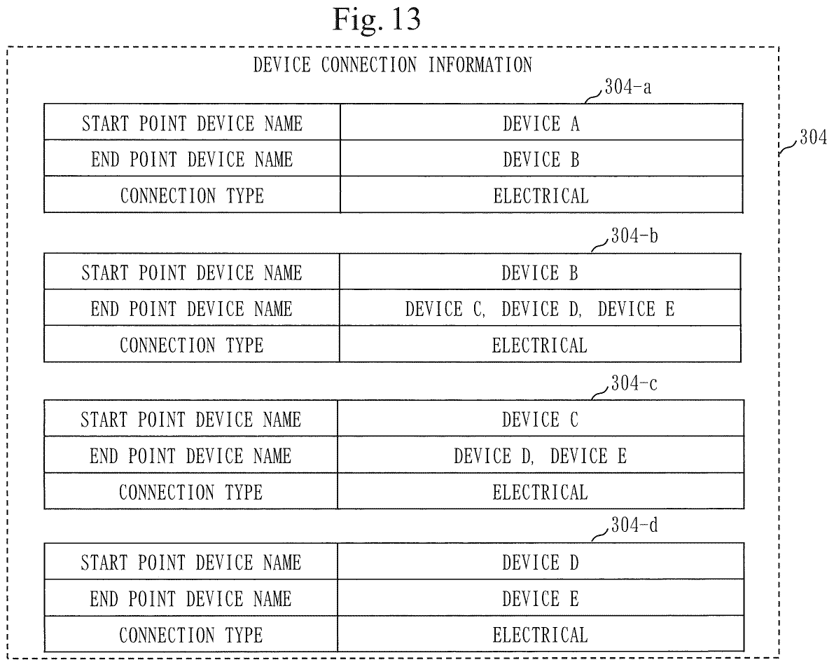

FIG. 13 illustrates an example of the device connection information 304 in the pattern 1 (301-1) that has undergone an update by the update unit 102.

In FIG. 13, the device connection information 304-a and the device connection information 304-b are similar to those illustrated in FIG. 7.

In FIG. 13, device connection information 304-c and device connection information 304-d are added.

The device connection information 304-c and the device connection information 304-d configure the device connection information 304 added by the update by the update unit 102.

In the device connection information 304-c, the direct connection between the device C and the device D is described. Further, in the device connection information 304-c, the direct connection between the device C and the device E is described.

In the device connection information 304-d, the direct connection between the device D and the device E is described.

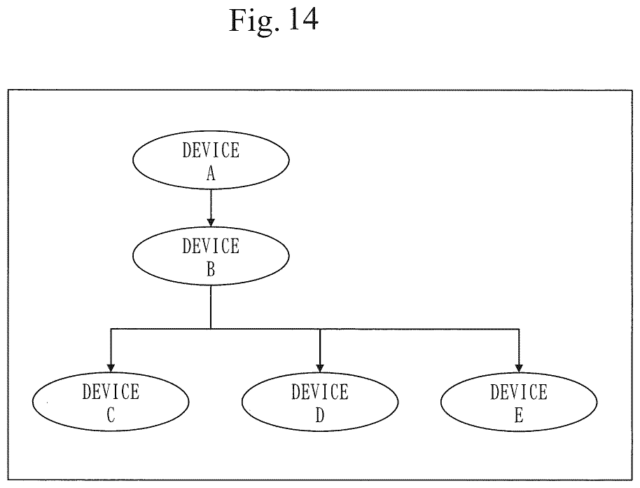

The updated device connection information 304 illustrated in FIG. 13 corresponds to a device configuration and connection relation among devices illustrated in FIG. 14.

In FIG. 14, the device A and the device B are directly connected and the device B, the device C, the device D, and the device E are directly connected.

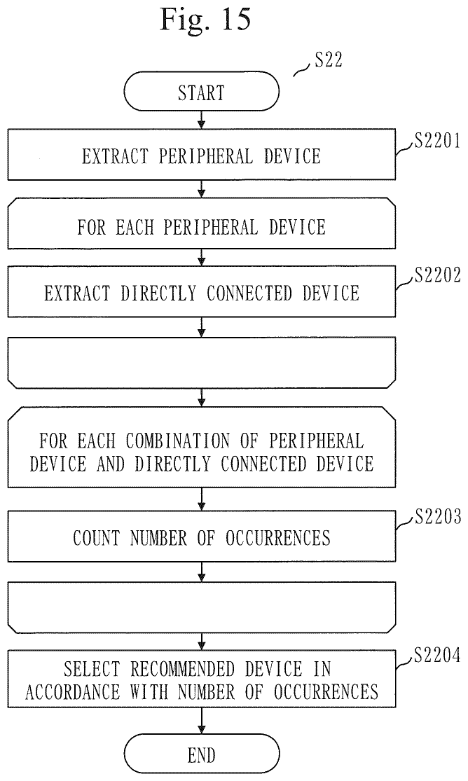

With reference to FIG. 15, subsequently, details of the recommended device selection process (step S22) illustrated in FIG. 10 will be described.

In step S2201, initially, the device recommendation unit 104 extracts peripheral devices.

The peripheral devices refer to devices that are directly connected to a position of device recommendation.

In case where the position of “?” in the new pattern 801 is designated by the user, the position of “?” becomes the position of device recommendation. In this case, the device recommendation unit 104 extracts the device B, the device C, and the device D that are directly connected to the position of “?”, as the peripheral devices.

In step S2202, subsequently, the device recommendation unit 104 extracts directly connected devices for the peripheral devices extracted in step S2201. The directly connected devices are devices connected directly to the peripheral devices.

Specifically, the device recommendation unit 104 scans the device connection information 304 to extract the directly connected devices connected directly to the peripheral devices.

Step S2202 is carried out for each of the peripheral devices extracted in step S2201.

For instance, the device recommendation unit 104 extracts the device C, the device D, and the device E as the directly connected devices for the device B from the device connection information 304 in the pattern 1 (301-1). Further, the device recommendation unit 104 extracts the device F as the directly connected device for the device B from the device connection information 304 in the pattern 2 (301-2). Further, the device recommendation unit 104 extracts the device G as the directly connected device for the device B from the device connection information 304 in the pattern 3 (301-3). Further, the device recommendation unit 104 extracts the device H as the directly connected device for the device B from the device connection information 304 in the pattern 4 (301-4).

Further, the device recommendation unit 104 extracts the device B, the device D, and the device E as the directly connected devices for the device C from the device connection information 304 in the pattern 1 (301-1), for instance. In the device connection information 304-b, as illustrated in FIG. 13, the direct connection between the device C and the device B is written. Further, in the device connection information 304-c, the direct connection between the device C and the device D and the direct connection between the device C and the device E are written. Therefore, the device recommendation unit 104 extracts the device B, the device D, and the device E as the directly connected devices for the device C. Similarly, the device recommendation unit 104 extracts the device F as the directly connected device for the device C from the device connection information 304 in the pattern 2 (301-2). Further, the device recommendation unit 104 extracts the device G as the directly connected device for the device C from the device connection information 304 in the pattern 3 (301-3). Further, the device recommendation unit 104 extracts the device H as the directly connected device for the device C from the device connection information 304 in the pattern 4 (301-4). Further, the device recommendation unit 104 extracts the device B′ as the directly connected device for the device C from the device connection information 304 in the pattern 5 (301-5).

Though illustration is omitted for the pattern 2 (301-2), the pattern 3 (301-3), the pattern 4 (301-4), and the pattern 5 (301-5), the device connection information 304 is updated by the extraction unit 101 and the update unit 102 for those patterns 301 as well, as with the device connection information 304-c and the device connection information 304-d. Therefore, the device D, the device E, a device F, a device G, and a device H are extracted in addition to the device B and the device B′, as the directly connected devices for the device C, as described above.

The device recommendation unit 104 similarly extracts the directly connected devices for the other peripheral devices as well.

In step S2203, subsequently, the device recommendation unit 104 counts numbers of occurrences of combinations of the peripheral devices and the directly connected devices.

Specifically, the device recommendation unit 104 scans the device connection information 304 to count the numbers of occurrences of the combinations of the peripheral devices and the directly connected devices.

Step S2203 is carried out for each of the combinations of the peripheral devices and the directly connected devices.

For instance, the number of occurrences of the combination of the peripheral device: the device B and the directly connected device: the device C is “4” because the combination occurs in the pattern 1 (301-1), the pattern 2 (301-2), the pattern 3 (301-3), and the pattern 4 (301-4).

Further, the number of occurrences of the combination of the peripheral device: the device B and the directly connected device: the device D is also “4” because the combination occurs in the pattern 1 (301-1), the pattern 2 (301-2), the pattern 3 (301-3), and the pattern 4 (301-4).

The number of occurrences of the combination of the peripheral device: the device B and the directly connected device: the device E is “1” because the combination occurs only in the pattern 1 (301-1).

The device recommendation unit 104 thus counts the number of occurrences of each of the combinations of the peripheral devices and the directly connected devices.

Incidentally, the device recommendation unit 104 may carry out step S2202 and step S2203 simultaneously.

That is, the device recommendation unit 104 may count the numbers of occurrences of the combinations of the peripheral devices and the directly connected devices while extracting the directly connected devices for the peripheral devices.

In step S2204, finally, the device recommendation unit 104 selects the recommended devices, in accordance with the numbers of occurrences.

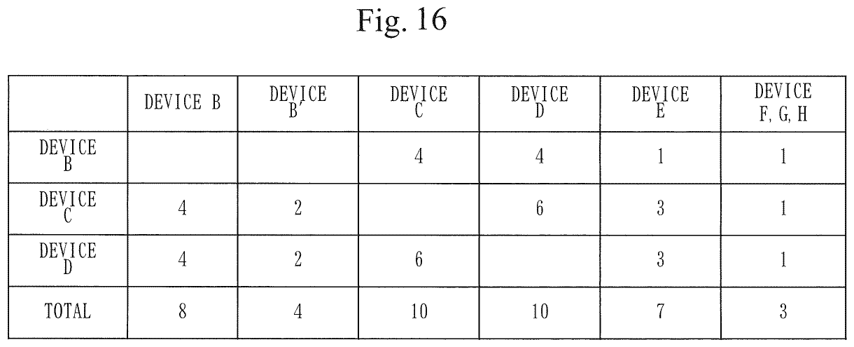

FIG. 16 illustrates results of counting of the numbers of occurrences of step S2203 in the patterns 301 illustrated in FIGS. 3 and 4.

In FIG. 16, a vertical axis represents the peripheral devices and a horizontal axis represents the directly connected devices.

For the peripheral device: the device B, the number of occurrences with each of the directly connected devices is as follows.
device C=4, device D=4, device E=1, device F=1, device G=1, device H=1

For the peripheral device: the device C, the number of occurrences with each of the directly connected devices is as follows.
device B=4, device B′=2, device D=6, device E=3, device F=1, device G=1, device H=1

For the peripheral device: the device D, the number of occurrences with each of the directly connected devices is as follows.
device B=4, device B′=2, device C=6, device E=3, device F=1, device G=1, device H=1

The device recommendation unit 104 calculates a total of the numbers of occurrences for each of the directly connected devices.

In FIG. 16, the total of the numbers of occurrences for each of the directly connected devices is as follows.
device B=8, device B′=4, device C=10, device D=10, device E=7, device F=3, device G=3, device H=3

The device recommendation unit 104 selects a desired number of directly connected devices, in descending order of the total of the numbers of occurrences, as the recommended devices.

For instance, the device recommendation unit 104 selects top three directly connected devices as the recommended devices. In this case, the device recommendation unit 104 selects the device C, the device D, and the device B as the recommended devices.

The communication unit 103 transmits a response specifying the recommended devices (the device C, the device D, and the device B) selected by the device recommendation unit 104, to the user terminal 500.

In the user terminal 500, the recommended devices (the device C, the device D, and the device B) are displayed in the recommended devices 204.

### ***Description of Effects of Embodiment***

In the present embodiment, as described above, when the devices are recommended based on relationships between the devices, the update of adding relationships between the directly connected devices to the device connection information is made and the recommended devices are selected based on the collaborative filtering with use of the updated device connection information. According to the present embodiment, accuracy of the recommendation can be thereby increased.

According to the present embodiment, consequently, facilities can be designed with utilization of the reliable devices and man-hours required for failure handling and man-hours required for replacement of failed devices can be reduced.

Incidentally, the procedure described in the present embodiment is one example.

Therefore, only a portion of the procedure described in the present embodiment may be embodied.

Further, at least a portion of the procedure described in the present embodiment and a procedure not described in the present embodiment may be embodied in combination.

Further, configurations and the procedure that have been described in the present embodiment may be altered as appropriate.

### ***Supplementary Description of Hardware Configuration***

Finally, supplementary description of the hardware configuration of the information processing apparatus 100 will be given.

The processor 901 illustrated in FIG. 17 is an IC (Integrated Circuit) to carry out processing.

The processor 901 is a CPU (Central Processing Unit), a DSP (Digital Signal Processor), or the like.

The main storage device 902 illustrated in FIG. 17 is a RAM (Random Access Memory).

The auxiliary storage device 903 illustrated in FIG. 17 is a ROM (Read Only Memory), a flash memory, an HDD (Hard Disk Drive), or the like.

The communication device 904 illustrated in FIG. 17 is an electronic circuit to carry out a communication process for data.

The communication device 904 is a communication chip or an NIC (Network Interface Card), for instance.

Further, in the auxiliary storage device 903, an OS (Operating System) is also stored.

Further, at least a portion of the OS is executed by the processor 901.

The processor 901 executes the programs that implement the functions of the update unit 102, the communication unit 103, and the device recommendation unit 104, while executing at least the portion of the OS.

The processor 901 executes the OS, so that task management, memory management, file management, communication control, and the like are carried out.

Further, at least any of information, data, signal values, and variable values that indicate results of the processes in the update unit 102, the communication unit 103, and the device recommendation unit 104 is stored in at least any of the main storage device 902, the auxiliary storage device 903, and a register and a cache memory in the processor 901.

Further, the programs that implement the functions of the update unit 102, the communication unit 103, and the device recommendation unit 104 may be stored in a portable recording medium such as magnetic disc, flexible disc, optical disc, compact disc, Blu-ray (registered trademark) disc, or DVD. Further, the portable recording media in which the programs that implement the functions of the update unit 102, the communication unit 103, and the device recommendation unit 104 are stored may be distributed.

Further, “unit” of at least any of the update unit 102, the communication unit 103, and the device recommendation unit 104 may be read as “circuit”, “step”, “procedure”, “process”, or “circuitry”.

Further, the information processing apparatus 100 may be implemented by a processing circuit. The processing circuit is a logic IC (Integrated Circuit), a GA (Gate Array), an ASIC (Application Specific Integrated Circuit), or an FPGA (Field-Programmable Gate Array), for instance.

In this configuration, each of the update unit 102, the communication unit 103, and the device recommendation unit 104 is implemented as a portion of the processing circuit.

Incidentally, a superordinate concept of the processor and the processing circuit is referred to as “processing circuitry”, herein.

That is, the processor and the processing circuit are specific examples of “processing circuitry”.

### REFERENCE SIGNS LIST

100: information processing apparatus; 101: extraction unit; 102: update unit; 103: communication unit; 104: device recommendation unit; 105: existing-pattern database; 201: new-pattern generation screen; 202: edit area; 203: device details; 204: recommended devices; 301: pattern; 302: pattern information; 303: device information; 304: device connection information; 500: user terminal; 801: new pattern; 901: processor; 902: main storage device; 903: auxiliary storage device; 904: communication device

1. An information processing apparatus comprising:
processing circuitry:
to analyze device connection information in which a device being a direct connection destination of each device of a plurality of connected devices is described and to extract, among two or more devices whose direct connection destination is common, a pair of devices each of which is not described as a device being a direct connection destination of the other device in the device connection information; and
to update the device connection information so that the device connection information describes that each one of the pair of devices extracted is a device being a direct connection destination of the other device.

2. The information processing apparatus according to claim 1, wherein
when a plurality of said pairs of the devices have been extracted, the processing circuitry updates description in the device connection information, for each of the pairs of the devices.

3. The information processing apparatus according to claim 1, wherein
as for a plurality of device connection patterns which each include a different combination of a plurality of devices and for each of which the device connection information corresponding to a connection status among the devices is provided, the processing circuitry analyzes the device connection information corresponding to each of the device connection patterns and extracts the pair of devices for each of the device connection patterns, and
the processing circuitry updates description in the device connection information corresponding to each of the device connection patterns.

4. The information processing apparatus according to claim 3, wherein
the processing circuitry carries out collaborative filtering with use of a plurality of pieces of device connection information for the plurality of device connection patterns that have been updated.

5. An information processing method comprising:
analyzing device connection information in which a device being a direct connection destination of each device of a plurality of connected devices is described and extracting, among two or more devices whose direct connection destination is common, a pair of devices each of which is not described as a device being a direct connection destination of the other device in the device connection information; and
updating the device connection information so that the device connection information describes that each one of the pair of devices extracted is a device being a direct connection destination of the other device.

6. A non-transitory computer readable medium storing an information processing program that causes a computer to execute:
an extraction process of analyzing device connection information in which a device being a direct connection destination of each device of a plurality of connected devices is described and of extracting, among two or more devices whose direct connection destination is common, a pair of devices each of which is not described as a device being a direct connection destination of the other device in the device connection information; and
an update process of updating the device connection information so that the device connection information describes that each one of the pair of devices extracted by the extraction process is a device being a direct connection destination of the other device.
